(19) United States
(12) Patent Application Publication
(10) Pub. No.: US 2025/0360790 A1
(43) Pub. Date: Nov. 27, 2025

(54) DISPLAY DEVICE INCLUDING MULTIPLE DISPLAY PANELS

(71) Applicant: SAMSUNG DISPLAY CO., LTD., YONGIN-SI (KR)

(72) Inventor: Dale YIM, Yongin-si (KR)

(21) Appl. No.: 19/020,568

(22) Filed: Jan. 14, 2025

(30) Foreign Application Priority Data
May 27, 2024 (KR) 10-2024-0068612

(51) Int. Cl. B60K 35/21; B60K 35/10; B60K 35/235; B60K 35/60; H10H 29/24; H10H 29/45

(52) U.S. Cl. CPC B60K 35/211; B60K 35/10; B60K 35/235; B60K 35/60; H10H 29/24; H10H 29/45; B60K 2360/1438

(57) ABSTRACT

A display device includes a first display panel including a plurality of first sub-pixels, a first display driver circuit configured to control an image display operation of the first display panel, a second display panel disposed in front of the first display panel and including a plurality of second sub-pixels and a plurality of light-transmitting areas disposed adjacent to the plurality of second sub-pixels, and a second display driver circuit configured to control an image display operation of the second display panel, wherein the second display panel is superimposed with the first display panel at a predetermined distance.

### CROSS-REFERENCE TO RELATED APPLICATION

This application claims priority under 35 U.S.C. 119 from Korean Patent Application No. 10-2024-0068612 filed on May 27, 2024, in the Korean Intellectual Property Office, the disclosure of which is herein incorporated by reference.

### BACKGROUND

### 1. Field of the Disclosure

The present disclosure relates to a display device, and more particularly to a display device including multiple display panels.

### 2. Discussion of Related Art

As information-oriented societies evolve, various demands are emerging for display devices. For example, display devices are being employed by a variety of electronic devices such as smart phones, digital cameras, laptop computers, navigation devices, and smart televisions, which may each have their own implementation specific demands. Display devices are increasingly being incorporated into automobiles and automotive electronic devices. Among these devices, safe operation is a relatively new demand.

### SUMMARY

Aspects of the present disclosure provide a display device in which a translucent second display panel can be moved to and placed in front of a first display panel fixed at a location in a vehicle, so that a three-dimensional effect image may be displayed through the superimposed first and second display panels.

Aspects of the present disclosure also provide a display device that can selectively display images of information about the status of a vehicle or content images on the first and second display panels depending on a status of the vehicle.

It should be noted that objects of the present disclosure are not limited to those mentioned herein; and other objects of the present disclosure will be apparent to those skilled in the art from the following descriptions.

According to an embodiment of the disclosure, a display device comprising a first display panel comprising a plurality of first sub-pixels, a first display driver circuit configured to control an image display operation of the first display panel, a second display panel disposed in front of the first display panel and comprising a plurality of second sub-pixels and a plurality of light-transmitting areas are disposed adjacent to the plurality of second sub-pixels, and a second display driver circuit configured to control an image display operation of the second display panel, wherein the second display panel is superimposed with the first display panel at a predetermined distance.

According to an embodiment of the disclosure, a display device comprising a first display panel configured to display a first image or a second image through a plurality of sub-pixels, a first display driver circuit configured to control an image display operation of the first display panel, a second display panel in which a plurality of second sub-pixels and a plurality of light-transmitting areas are alternately arranged to display the second image through the plurality of second sub-pixels, a second display driver circuit configured to control an image display operation of the second display panel; and a touch sensing unit formed on a front surface of the second display panel, wherein the plurality of light-transmitting areas of the second display panel is configured to transmit light emitted by the first display panel, and the second display panel is superimposed with the first display panel at a predetermined distance in front of the first display panel.

According to an embodiment of the present disclosure, a vehicle control system may include a first display panel including a first plurality of sub-pixels, a first display driver circuit configured to control an operation of the first display panel, a second display panel rotatably disposed in front of the first display panel and including a second plurality of sub-pixels and light-transmitting areas, and a second display driver circuit configured to control an operation of the second display panel.

According to an embodiment of the present disclosure, a display device may allow a translucent second display panel to be moved and placed in front of a first display panel, wherein a three-dimensional effect may be perceived by a user or driver. Accordingly, drivers may more effectively utilize content images and improve their satisfaction.

In addition, according to an embodiment of the present disclosure, a display device allows images of information about the status of the vehicle and/or three-dimensional content images to be displayed on the first and second display panels selectively depending on a status of the vehicle, which may improve safely in the vehicle.

It should be noted that effects of the present disclosure are not limited to those described herein and other effects of the present disclosure will be apparent to those skilled in the art from the following descriptions.

### BRIEF DESCRIPTION OF THE DRAWINGS

These and other aspects and features of the present disclosure will become more apparent by describing in detail embodiments thereof with reference to the attached drawings, in which:

FIG. 1 is a view showing an application example of a display device according to an embodiment of the present disclosure.

FIG. 2 is a plan view showing a configuration of the first display panel according to an embodiment of the present disclosure.

FIG. 3 is a plan view showing a configuration of the second display panel according to an embodiment of the present disclosure.

FIG. 4 is a cross-sectional view showing a side structure of the second display panel shown in FIG. 3.

FIG. 5 is a layout diagram schematically showing the structure of the second display panel shown in FIG. 3 and FIG. 4.

FIG. 6 is a cross-sectional view schematically showing the structure taken along line A-A of in FIG. 5.

FIG. 7 is a cross-sectional view specifically showing the cross-sectional structure of the first blue pixel, the red pixel and the light-transmitting area shown in FIG. 6.

FIG. 8 is an enlarged cross-sectional view of a light-emitting unit of the first blue pixel shown in FIG. 7.

FIG. 9 is a view showing a displayed image indicating information about the status of a vehicle as the first and second display panels are superimposed during driving.

FIG. 10 is a view showing a content image when the first and second display panels are superimposed while the vehicle is stationary.

FIG. 11 is another view showing a content image when the first and second display panels are superimposed while the vehicle is stationary.

FIG. 12 is a schematic block diagram illustrating a vehicle control system according to an embodiment of the present disclosure.

FIG. 13 is a flow diagram illustrating a method according to an embodiment of the present disclosure.

### DETAILED DESCRIPTION

The present disclosure will now be described more fully hereinafter with reference to the accompanying drawings, in which preferred embodiments of the disclosure are shown. This disclosure may, however, be embodied in different forms and should not be construed as limited to embodiments set forth herein. Rather, embodiments are provided so that this disclosure will be thorough and complete, and will filly convey the scope of the disclosure to those skilled in the art.

It will also be understood that when a layer is referred to as being “on” another layer or substrate, the layer can be directly on the other layer or substrate, or intervening layers may also be present. In contrast, when an element is referred to as being “directly on” another element, there may be no intervening elements present. The same reference numbers indicate the same components throughout the specification.

It will be understood that, although the terms “first,” “second,” etc. may be used herein to describe various elements, these elements should not be limited by these terms. These terms may be used to distinguish elements. For instance, a first element discussed below could be termed a second element without departing from the teachings of the present disclosure. Similarly, the second element could also be termed the first element.

Features of different embodiments of the present disclosure may be implemented individually or combined with each other, in part or in whole. Embodiments may be implemented independently of each other or may be implemented together in an association.

Hereinafter, embodiments of the present disclosure will be described in detail with reference to the accompanying drawings.

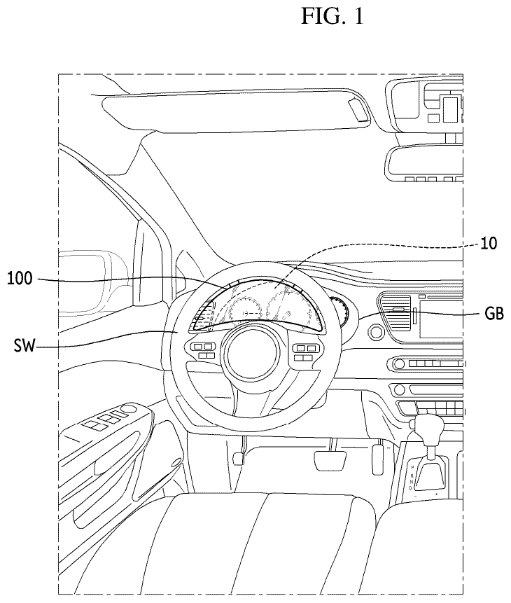

FIG. 1 is a view showing an application example of a display device according to an embodiment of the present disclosure.

Referring to FIG. 1, the display device according to an embodiment may include a first display panel 10 and a second display panel 100. The first and second display panels 10 and 100 may be superimposed. The first and second display panels 10 and 100, which may be superimposed, may be applied to an instrument panel of a vehicle, a center information display (CID) of a center fascia, or a dashboard. According to an embodiment of the present disclosure, the first display panel 10 may be fixedly disposed at a location GB of a vehicle. For example, the first display panel 10 may be fixedly disposed at a location GB of a vehicle where information about the status of the vehicle may be displayed (e.g., the location of the instrument cluster). The second display panel 100 may be disposed in front of the first display panel 10. For example, the second display panel 100 may be fastened to a steering wheel SW. The second display panel 100 may be fastened to the steering wheel SW by a separate fastening member. According to a rotational position of the steering when SW, the second display panel 100 may be located in the front of the first display panel 10. According to a rotational position of the steering when SW, the second display panel 100 may be partially or fulling disposed in the front of the first display panel 10

According to another embodiment, at least one of the first or second display panels 10 and 100 of a display device may be formed integrally with the instrument cluster of a vehicle. The instrument cluster of the vehicle may be, for example, the center dashboard or passenger seat dashboard. The first and second display panels 10 and 100 applied to the dashboard of a vehicle may be superimposed. More particularly, the first and second display panels 10 and 100 applied to the dashboard of a vehicle may be superimposed, and a display of each the first and second display panels 10 and 100 may be superimposed from a viewpoint of a user. The information about the status of the vehicle, navigation information, audio and video content information, air conditioning device control information, or electronic device control information for controlling options and functions may be displayed in predetermined divided areas of the first and second display panels 10 and 100.

As another example, the superimposed first and second display panels 10 and 100 may be used as a display unit of a television, a laptop computer, a PC monitor, an electronic billboard, or an Internet of Things (IoT) device. For another example, the first and second display panels 10 and 100 arranged to be superimposed may be applied to portable electronic devices such as a tablet PC, a mobile communications terminal, an electronic notebook, an electronic book, a portable multimedia player (PMP), or an ultra mobile PC (UMPC). Alternatively, the first and second display panels 10 and 100 may be applied to wearable devices such as a smart watch, a watch phone, a glasses-type display, or a head-mounted display (HMD) device.

The display devices according to some embodiments may be variously classified by the way in which images may be displayed. For example, the display device may be classified into, and implemented as, an organic light-emitting display device (OLED), an inorganic light-emitting display device (inorganic EL), a quantum-dot light-emitting display device (QED), a micro LED display device (micro-LED), a nano LED display device (nano-LED), a plasma display device (PDP), a field emission display device (FED), a liquid-crystal display device (LCD), or an electrophoretic display device (EPD). However, embodiments are not limited thereto, and the display device may be implemented with various technologies. In the following description, an organic light-emitting display device (OLED) will be described as an example of the display device. The organic light-emitting display device OLED may be simply referred to as the display device 10 unless explicitly described. It is, however, to be understood that embodiments of the present disclosure are not limited to the organic light-emitting display device (OLED), and any display device well known in the art may be employed as the display device without departing from the scope of the present disclosure.

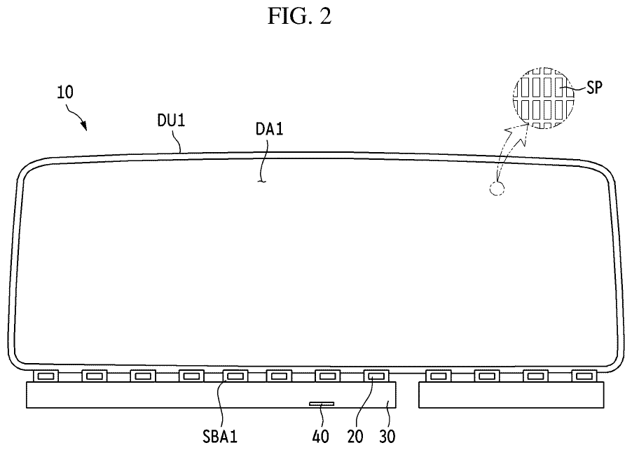

FIG. 2 is a plan view showing a configuration of the first display panel 10 according to an embodiment of the present disclosure.

Referring to FIG. 2, the first display panel 10 may include a first image display unit DU1 that displays images through a plurality of sub-pixels SP, a plurality of first data driver circuits 20, a first circuit board 30, and a first display driver circuit 40.

The first image display unit DU1 of the first display panel 10 may receive data signals from the plurality of first data driver circuits 20 and gate signals from the first display driver circuit 40. In addition, the first image display unit DU1 may display images through the plurality of sub-pixels SP arranged in the first display area DA1 in response to the data and gate signals.

In the first display area DA1, light may exit from emission areas or opening areas of the sub-pixels SP to display images. To this end, each of the sub-pixels SP in the first display device DA1 may include a pixel circuit including switching elements, a pixel-defining layer that defines the emission area or the opening area, and a self-light-emitting element.

The first circuit board 30 may be attached on a pad of the first display panel 10 using an anisotropic conductive film (ACF) connection. However, embodiments are not limited thereto. For example, the first circuit board 30 and the first display panel 10 may be variously attached, or may be directly attached by solder or a connector part.

The first data driver circuits 20 may be implemented as integrated circuits (IC). The first data driver circuits 20 may be disposed on the respective printed circuit films by the chip-on-glass (COG) technique, the chip-on-plastic (COP) technique, or ultrasonic bonding. The first data driver circuits 20 may convert digital image data into analog data signals in response to the data control signal from the first display driver circuit 40 and may provide the data signals to the sub-pixels SP. The first data driver circuits 20 may provide the data signals to data lines connected to the sub-pixels SP.

The first display driver circuit 40 may be implemented as an integrated circuit. The first display driver circuit 40 may be mounted on the first display panel 10 or on the first circuit board 30 by the COG technique, the COP technique, or ultrasonic bonding. The first display driver circuit 40 may operate as a main processor or may be formed integrally with the main processor. The first display driver circuit 40 may output gate and data control signals for driving the sub-pixels SP of the first image display unit DU1 and image data. In addition, the first display driver circuit 40 may provide supply voltages to power lines of the first image display unit DU1 and may provide gate control signals to a separate gate driver. However, embodiments are not limited thereto, and the first display driver circuit 40 may provide other signals.

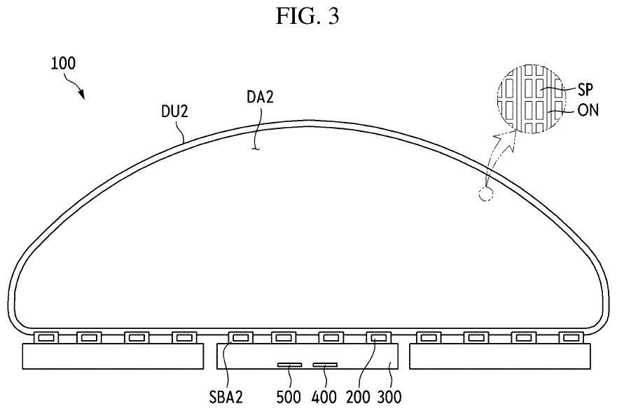

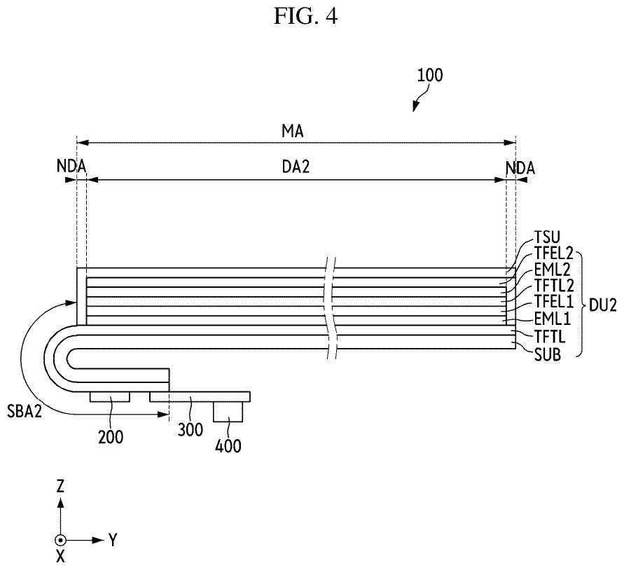

FIG. 3 is a plan view showing a configuration of the second display panel according to an embodiment of the present disclosure. FIG. 4 is a cross-sectional view showing a side structure of the second display panel shown in FIG. 3.

Referring to FIG. 3 and FIG. 4, the second display panel 100 may include a second image display unit DU2 in which a plurality of sub-pixels SP and light-transmitting areas ON may be arranged to display images through the plurality of sub-pixels SP, a plurality of second data driver circuits 200, a second circuit board 300, and a second display driver circuit 400. As shown in FIG. 2, the light-transmitting areas ON may be omitted from the first image display unit DU1.

The second image display unit DU2 of the second display panel 100 may receive data signals from the plurality of second data driver circuits 200 and gate signals from the second display driver circuit 400. In addition, the second image display unit DU2 may display images through the plurality of sub-pixels SP arranged in the second display area DA2 in response to the data and gate signals.

In the second display area DA2 of the second image display unit DU2, a plurality of sub-pixels SP for displaying images and a plurality of light-transmitting areas ON may be disposed adjacent to each other. For example, the plurality of sub-pixels SP for displaying images and the light-transmitting areas ON may be arranged alternately. For example, each light-transmitting area ON may be a linear area display between groups of the plurality of sub-pixels SP. However, embodiments are not limited thereto, and different arrangements of the plurality of sub-pixels SP and the light-transmitting areas ON may be implemented.

Light may exit from the emission areas or the opening areas of the sub-pixels SP arranged in the second display area DA2. The light-transmitting areas ON may be transparent, and light may be emitted from the front or rear side. In the second image display unit DU2, transparent light-transmitting areas ON may be arranged in parallel with the sub-pixels SP alternating with each other, so that the second image display unit DU2 may be transparent or translucent. For example, the light-transmitting areas ON of the second image display unit DU2 may transmit light emitted by the first display panel DA1.

In the present disclosure, translucent may describes a display area that allows light to pass, and a transparent display may allow all light to pass. However, in the present disclosure, the terms translucent and transparent may be used interchangeably to describe a material that allows at least a portion of light to pass, unless explicitly described otherwise. That is, the second display panel 100 may be a transparent display, that may allow at least a portion of light to pass. According to an embodiment, the second display panel 100 may be controllable to allow a certain amount of light to pass. For example, the second display panel 100 may be controllable to block about 10% of light, about 50% of light, or about 80% of light. In an embodiment, different portions of the second display panel 100 may be controllable to block different amounts of light.

Referring to FIG. 4, the second display panel 100 may be divided into a main area MA and a subsidiary area SBA. The main area MA may include a second display area DA2 in which the sub-pixels SP for displaying images and the light-transmitting areas ON may be arranged, and a non-display area NDA around the second display area DA2. In the second display area DA2, light may exit from the emission areas or the opening areas of the sub-pixels SP to display images. Light may be emitted by the light-transmitting areas ON from the front or rear side.

The sub-pixels SP of the second display area DA2 may overlap one another and may be formed and arranged as a double layer. Each of the overlapping sub-pixels SP may include a pixel circuit including switching elements, a pixel-defining layer defining an emission area or an opening area, and a self-luminous element.

The non-display area NDA may be disposed on at least a portion of an outer side of the second display area DA2. The non-display area NDA may be defined as the edge of the main area MA of the second display panel 100. The non-display area NDA may include a gate driver (not shown) that applies gate signals to gate lines, and fan-out lines (not shown) that connect the display driver circuit 400 with the second display area DA2.

The subsidiary area SBA may be extended from a side of the main area MA. The subsidiary area SUB may include a flexible material that may be bent, folded, or rolled. For example, when the subsidiary area SBA is bent, the subsidiary area SBA may overlap the main area MA in the thickness direction (z-axis direction). The subsidiary area SBA may include one or more pads connected to the second display driver circuit 400 and the second circuit board 300. Optionally, the subsidiary area SBA may be eliminated, and the second display driver circuit 400 and the pads may be disposed in the non-display area NDA.

The second circuit board 300 may be attached on the pad of the second display panel 100 using an anisotropic conductive film (ACF) connection. However, embodiments are not limited thereto. For example, the second circuit board 300 and the second display panel 100 may be variously attached, or may be directly attached by solder or a connector part. Lead lines of the second circuit board 300 may be electrically connected to the pads of the second display panel 100. The second circuit board 300 may be a flexible printed circuit board (FPCB), a printed circuit board (PCB), or a flexible film such as a chip-on-film (COF).

The second data driver circuits 200 may be implemented as integrated circuits (IC) and may be disposed on the respective printed circuit films by the chip-on-glass (COG) technique, the chip-on-plastic (COP) technique, or ultrasonic bonding. The second data driver circuits 200 may convert digital image data into analog data signals in response to the data control signal from the second display driver circuit 400 and provide the data signals to the sub-pixels SP. The second data driver circuits 200 may provide the data signals to data lines connected to the sub-pixels SP.

The second display driver circuit 400 may be implemented as an integrated circuit and may be mounted on the second display panel 100 or on the second circuit board 300 by the COG technique, the COP technique, or ultrasonic bonding. The second display driver circuit 400 may operate as a main processor or may be formed integrally with the main processor. The second display driver circuit 400 may output gate and data control signals for driving the sub-pixels SP of the second image display unit DU2 and image data. In addition, the second display driver circuit 400 may provide supply voltages to power lines of the second image display unit DU2, and may also provide gate control signals to a separate gate driver.

The second display driver circuit 400 may receive touch data from a touch driver circuit 500 to determine touch coordinates of an input interaction with the second display panel 100, and may generate digital video data based on the touch coordinates. The interaction may be a touch of a user's finger or a tool, such as a stylus or an electronic pen. In addition, the second display driver circuit 400 may execute an application associated with an icon displayed on the touch coordinates. For another example, the second display driver circuit 400 may receive coordinate data from an electronic pen to determine the touch coordinates of the electronic pen, and may generate digital video data according to the touch coordinates or may execute an application indicated by an icon displayed at the touch coordinates of the electronic pen.

The touch driver circuit 500 may be mounted on the second circuit board 300. The touch driver circuit 500 may be electrically and physically connected to the touch sensing unit TSU. The touch driver circuit 500 may be implemented as an integrated circuit (IC). As described herein, the touch driver circuit 500 may apply touch driving signals to the touch electrodes of the touch sensing unit TSU. The touch driving signal may be a pulse signal having a predetermined frequency. The touch driver circuit 500 measures in real time changes in the mutual capacitance of each of a plurality of touch nodes formed by the touch electrodes. Specifically, the touch driver circuit 500 may measure changes in the capacitance of the touch nodes based on the frequency, the voltage level and changes in the amount of current of touch sensing signals received through the touch electrodes. In this manner, the touch driver circuit 500 may determine whether there is an input interaction such as a user's touch or near proximity, based on a change in the mutual capacitance of each of the touch nodes. For example, the touch sensing unit TSU may detect a touch position associated with an input. The input interaction may be by a part of a user's body (e.g., finger) or another tool, such as a stylus or an electronic pen.

Incidentally, the substrate SUB of the second display panel 100 shown in FIG. 4 may be a base substrate or a base member. The substrate SUB may be a flexible substrate that can be bent, folded, or rolled. For example, the substrate SUB may include, but is not limited to, a glass material or a metal material. As another example, the substrate SUB may include a polymer resin such as polyimide PI.

As described herein, the sub-pixels SP may overlap one another and may be formed and arranged as a double layer in the second display area DA2 of the second display panel 100. Each of the overlapping sub-pixels SP may include a pixel circuit including switching elements, a pixel-defining layer defining an emission area or an opening area, and a self-luminous element.

Specifically, in the structure where the sub-pixels SP overlap one another such that they may be formed and arranged as a double layer, a first thin-film transistor layer TFTL1 is disposed firstly on the substrate SUB. The first thin-film transistor layer TFTL1 may include a plurality of thin-film transistors forming pixel circuits of the sub-pixels SP. The first thin-film transistor layer TFTL1 may include gate lines, data lines, voltage lines, gate control lines, fan-out lines for connecting the second data driver circuit 200 with the data lines, and/or lead lines for connecting the second display driver circuit 400 with the pad. When a separated gate driver is formed on a side of the non-display area NDA of the second display panel 100, the gate driver may also include thin-film transistors.

The first thin-film transistor layer TFTL1 may be disposed in the second display area DA2, the non-display area NDA and the subsidiary area SBA, excluding the light-transmitting areas ON. The thin-film transistors in the first thin-film transistor layer TFTL1 for each of the pixels, the gate lines, the data lines and the voltage lines may be disposed in the second display area DA2. The gate control lines and the fan-out lines in the first thin-film transistor layer TFTL1 may be disposed in the non-display area NDA. The lead lines of the first thin-film transistor layer TFTL1 may be disposed in the subsidiary area SBA.

A first emission material layer EML1 may be disposed on the first thin-film transistor layer TFTL1. The first emission material layer EML1 may include a plurality of light-emitting elements in each of which a first electrode, an emissive layer and a second electrode may be stacked on one another sequentially to emit light, and a pixel-defining layer for defining each of the sub-pixels SP. The plurality of light-emitting elements in the first emission material layer EML1 may be disposed in the second display area DA2.

A first encapsulation layer TFEL1 may cover the top and side surfaces of the first emission material layer EML1 and can protect the first emission material layer EML1. The first encapsulation layer TFEL1 may include at least one inorganic layer and at least one organic layer for encapsulating the first emission material layer EML1.

With the sub-pixels SP and the light-transmitting areas ON arranged on the substrate SUB, additional sub-pixels SP may be further formed on the front side of the previously arranged sub-pixels SP. To this end, a second thin-film transistor layer TFTL2 is formed on the front side of the first encapsulation layer TFEL1. The second thin-film transistor layer TFTL2 may be disposed in the second display area DA2, the non-display area NDA and the subsidiary area SBA, excluding the light-transmitting areas ON. The thin-film transistors in the second thin-film transistor layer TFTL2 for each of the pixels, the gate lines, the data lines and the voltage lines may be disposed in the second display area DA2 on the front side of the first encapsulation layer TFEL1. The gate control lines and the fan-out lines in the second thin-film transistor layer TFTL2 may be disposed in the non-display area NDA.

A second emission material layer EML2 may be disposed on the second thin-film transistor layer TFTL2. The second emission material layer EML2 may include a plurality of light-emitting elements in each of which a first electrode, an emissive layer and a second electrode may be stacked on one another sequentially to emit light, and a pixel-defining layer for defining each of the sub-pixels SP. The plurality of light-emitting elements in the second emission material layer EML2 may be disposed in the second display area DA2.

A second encapsulation layer TFEL2 may cover the top and side surfaces of the second emission material layer EML2 and can protect the second emission material layer EML2. The second encapsulation layer TFEL2 may include at least one inorganic layer and at least one organic layer for encapsulating the second emission material layer EML2.

The touch sensing unit TSU may be disposed on the second encapsulation layer TFEL2. The touch sensing unit TSU may include a plurality of touch electrodes for sensing a user's touch by capacitive sensing, and touch lines connecting the plurality of touch electrodes with the touch driver circuit 500. For example, the touch sensing unit TSU may sense a user's touch by self-capacitance sensing or mutual capacitance sensing.

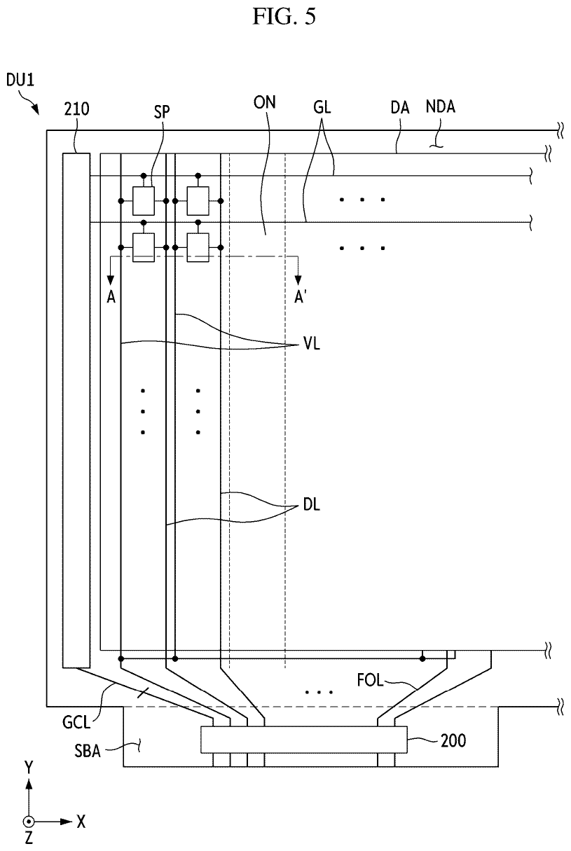

FIG. 5 is a layout diagram schematically showing the structure of the second display panel shown in FIG. 3 and FIG. 4. Specifically, FIG. 5 is a layout diagram showing the second display area DA2 and the non-display area NDA of the second image display unit DU before the touch sensing unit TSU is formed.

The second display panel 100 may be a see-through display or transparent display. The second display panel 100 may be a transparent micro LED display device. The second display panel 100 may be transparent or translucent in either a turned-off state or a turned-on state.

The second display area DA2 displays images and may be translucent, and may be defined as the central area of the second display panel 100. The second display area DA2 includes a plurality of sub-pixels SP overlapping one another as a double layer, a plurality of gate lines GL, a plurality of data lines DL, a plurality of voltage lines VL, and a plurality of light-transmitting areas ON. Each of the plurality of sub-pixels SP may be defined as the minimum unit that outputs light, and the light-transmitting areas ON is a transparent area that transmits light on the front or rear side.

The plurality of sub-pixels SP overlapping one another as a double layer and the light-transmitting areas ON may be alternately arranged in parallel with each other. For example, the plurality of sub-pixels SP overlapping one another as a double layer and a light-transmitting area ON may be arranged side by side, alternating with each other in the vertical direction or horizontal direction.

The gate lines GL may be formed as a double layer where they overlap one another, and may provide gate signals received from the gate driver 210 of the non-display area NDA to the sub-pixels SP formed as the double layer. The plurality of gate lines GL may be extended in the x-axis direction and may be spaced apart from one another in the y-axis direction crossing the x-axis direction.

The data lines DL may be formed as a double layer where they overlap one another, and may provide the data voltage received from the second display driver circuit 400 to each of the sub-pixels SP formed as a double layer. The plurality of data lines DL may be extended in the y-axis direction and may be spaced apart from one another in the x-axis direction.

The voltage lines VL may provide the supply voltage received from the second display driver circuit 400 to the respective sub-pixels SP. The supply voltage may be at least one of a driving voltage, an initialization voltage, or a reference voltage. The plurality of voltage lines VL may be extended in the y-axis direction and may be spaced apart from one another in the x-axis direction.

The non-display area NDA may surround the second display area DA2. The non-display area NDA may include the gate driver 210, fan-out lines FOL, and gate control lines GCL. The gate driver 210 may generate a plurality of gate signals based on the gate control signal, and may sequentially supply the plurality of gate signals to the plurality of gate lines GL in a predetermined order.

The fan-out lines FOL may be extended from the second data driver circuit 200 to the second display area DA2. The fan-out lines FOL may provide the data signal (or data voltage) received from the second data driver circuit 200 to the data lines DL.

The gate control line GCL may be extended from the second display driver circuit 400 to the gate driver 210. The gate control line GCL may provide the gate control signal received from the second display driver circuit 400 to the gate driver 210.

The second display driver circuit 400 may output signals and voltages for driving the second display panel 100 to the fan-out lines FOL. The second display driver circuit 400 may provide data voltages to the data lines DL through the fan-out lines FOL. The data voltages may be applied to the plurality of sub-pixels SP, so that the luminance of the plurality of sub-pixels SP may be determined. The second display driver circuit 400 may provide a gate control signal to the gate driver 210 through the gate control lines GCL.

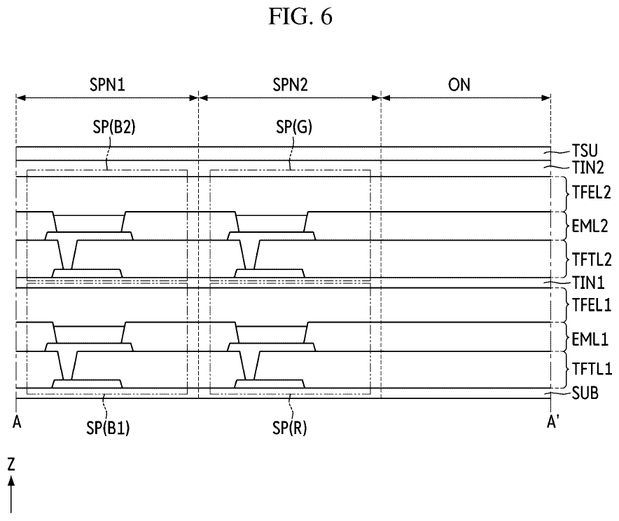

FIG. 6 is a cross-sectional view schematically showing the structure taken along line A-A of in FIG. 5.

Referring to FIG. 6, the sub-pixels SP may overlap one another and may be formed and arranged as a double layer in the second display area DA2 of the second display panel 100. Each of the overlapping sub-pixels SP may include a pixel circuit including switching elements, a pixel-defining layer defining an emission area or an opening area, and a self-luminous element.

Specifically, the second display area DA2 of the second display panel 100 includes a first pixel area SPN1, a second pixel area SPN2, and a light-transmitting area ON.

The first pixel area SPN1 includes first and second blue sub-pixels SP(B1) and SP(B2) that overlap each other and may be formed as a double layer.

The second pixel area SPN2 includes a red sub-pixel SP(R) and a green sub-pixel SP(G) overlapping each other and formed as a double layer.

The light-transmitting area ON is transparent and transmits light on therethrough. To this end, the light-transmitting area ON may include at least one organic layer or inorganic layer. In addition, the light-transmitting area ON may further include at least one opening as a structure for transmitting light to the front side or the rear side thereof.

In the second display area DA2 of the second display panel 100, the first pixel area SPN1, the second pixel area SPN2 and the light-transmitting area ON may be sequentially and repeatedly arranged side-by-side in parallel stripes. For example, these parallel stripes may be arranged as horizontal or vertical stripes.

On the substrate SUB of the second display area DA2, the first thin-film transistor layer TFTL1 including a plurality of thin-film transistors forming the pixel circuits of the first blue sub-pixels SP(B1) and the red sub-pixels SP(R) is firstly formed. The first thin-film transistor layer TFTL1 may be disposed in the second display area DA2, the non-display area NDA and the subsidiary area SBA, excluding the light-transmitting areas ON.

On the front surface of the first thin-film transistor layer TFTL1 formed in the second display area DA2, the first emission material layer EML1 including light-emitting elements of the first blue sub-pixels SP(B1) and the red sub-pixels SP(R) is formed. Specifically, the first emission material layer EML1 may include a plurality of light-emitting elements in each of which a first electrode, an emissive layer and a second electrode may be stacked on one another sequentially to emit light, and a pixel-defining layer for defining first blue sub-pixels SP(B1) and red sub-pixels SP(R).

The first encapsulation layer TFEL1 is formed on the front and side surfaces of the first emission material layer EML1. The first encapsulation layer TFEL1 may include at least one organic layer that encapsulates the first emission material layer EML1.

A first protective layer TIN1 may be further formed on the front surface of the first encapsulation layer TFEL1 to cover and protect the entire first encapsulation layer TFEL1, including the first emission material layer EML1, and to provide flat surface over it. The first protective layer TIN1 may include at least one inorganic layer.

A transparent organic or a transparent inorganic layer may be formed in the light-transmitting area ON, and an opening may be further formed in the light-transmitting area ON in order to increase transmittance.

With the first blue sub-pixels SP(B1) and the red sub-pixels SP(R) arranged on the substrate SUB, second blue sub-pixels SP(B2) and green sub-pixels SP(G) may be further disposed on the front surface of the first blue sub-pixels SP(B1) and the red sub-pixels SP(R).

To this end, on the front side of the first blue sub-pixels SP(B1) and the red sub-pixels SP(R), the second thin-film transistor layer TFTL2 is formed, which includes a plurality of thin-film transistors forming pixel circuits of the second blue sub-pixels SP(B2) and the green sub-pixels SP(G). The second thin-film transistor layer TFTL2 may be disposed in the second display area DA2, the non-display area NDA and the subsidiary area SBA, excluding the light-transmitting areas ON.

Subsequently, on the front side of the second thin-film transistor layer TFTL2, the second emission material layer EML2 is formed, which includes light-emitting elements of the second blue sub-pixels SP(B2) and the green sub-pixels SP(G). Specifically, the second emission material layer EML2 may include a plurality of light-emitting elements in each of which a first electrode, an emissive layer and a second electrode may be stacked on one another sequentially to emit light, and a pixel-defining layer for defining second blue sub-pixels SP(B2) and green sub-pixels SP(G).

The second encapsulation layer TFEL2 is formed on the front and side surfaces of the second emission material layer EML2. The second encapsulation layer TFEL2 may include at least one organic layer that encapsulates the second emission material layer EML2.

A second protective layer TIN2 may be further formed on the front surface of the second encapsulation layer TFEL2 to cover and protect the entire second encapsulation layer TFEL2, including the second emission material layer EML2, and to provide flat surface over it. The second protective layer TIN2 may include at least one inorganic layer.

An organic layer or an inorganic layer made of a transparent material is formed in the light-transmitting area ON, and an opening may be further formed in the light-transmitting area ON in order to increase transmittance.

The touch sensing unit TSU may be disposed on the second encapsulation layer TFEL2. The touch sensing unit TSU may include a plurality of touch electrodes for sensing a user's touch by capacitive sensing, and touch lines connecting the plurality of touch electrodes with the touch driver circuit 500.

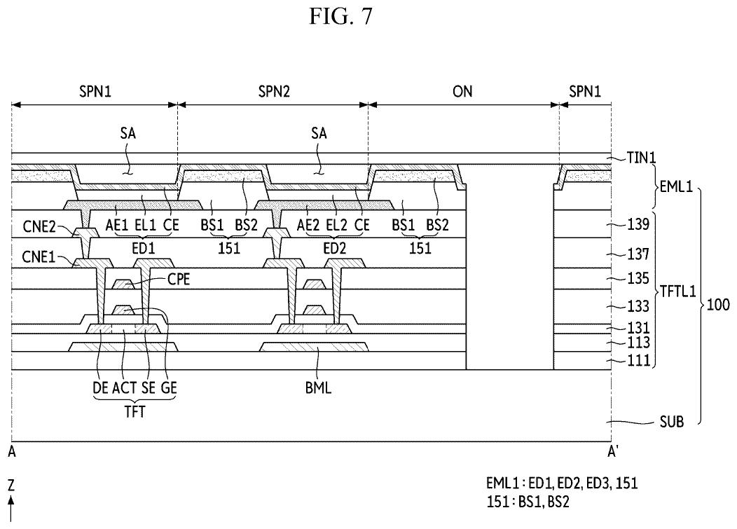

FIG. 7 is a cross-sectional view specifically showing the cross-sectional structure of the first blue pixel, the red pixel and the light-transmitting area shown in FIG. 6.

Referring to FIG. 7, the first thin-film transistor layer TFTL1 in which thin-film transistors of the first blue pixel SP(B1) and the red pixel SP(R) may be formed is disposed on the substrate SUB.

The first thin-film transistor layer TFTL1 may include a first buffer layer 111, a bottom metal layer BML, a second buffer layer 113, a thin-film transistor TFT, a gate insulator 131, a first interlayer dielectric layer 133, a capacitor electrode CPE, a second interlayer dielectric layer 135, a first connection electrode CNE1, a first passivation layer 137, a second connection electrode CNE2 and a second passivation layer 139.

The first buffer layer 111 may be disposed on the substrate SUB. The first buffer layer 111 may include an inorganic layer capable of inhibiting or preventing permeation of air or moisture. For example, the first buffer layer 111 may include a plurality of inorganic layers stacked on one another alternately.

The bottom metal layer BML may be disposed on the first buffer layer 111. For example, the bottom metal layer BML may be made up of a single layer or multiple layers of one of molybdenum (Mo), aluminum (Al), chromium (Cr), gold (Au), titanium (Ti), nickel (Ni), neodymium (Nd), or copper (Cu) or an alloy thereof.

The second buffer layer 113 may cover the first buffer layer 111 and the bottom metal layer BML. The second buffer layer 113 may include an inorganic layer capable of preventing permeation of air or moisture. For example, the second buffer layer 113 may include a plurality of inorganic layers stacked on one another alternately.

The thin-film transistor TFT may be disposed on the second buffer layer 113 and may form a pixel circuit of each of a plurality of pixels. The thin-film transistor TFT may be a driving transistor or a switching transistor of the pixel circuit. The thin-film transistor TFT may include a semiconductor layer ACT, a source electrode SE, a drain electrode DE and a gate electrode GE. The thin-film transistor TFT may include an oxide thin-film transistor (oxide TFT) or a low-temperature polysilicon thin-film transistor (LTPS).

The semiconductor layer ACT may be disposed on the second buffer layer 113. The semiconductor layer ACT may overlap the bottom metal layer BML and the gate electrode GE in the thickness direction and may be insulated from the gate electrode GE by the gate insulator 131. The material of a part of the semiconductor layer ACT may be made conductive to form the source electrode SE and the drain electrode DE.

The gate electrode GE may be disposed on the gate insulator 131. The gate electrode GE may overlap the semiconductor layer ACT with the gate insulator 131 interposed therebetween.

The gate insulator 131 may be disposed on the semiconductor layer ACT. For example, the gate insulator 131 may cover the semiconductor layer ACT and the second buffer layer 113, and may insulate the semiconductor layer ACT from the gate electrode GE. The gate insulator 131 may include a contact hole through which the first connection electrode CNE1 passes.

The first interlayer dielectric layer 133 may cover the gate electrode GE and the gate insulator 131. The first interlayer dielectric layer 133 may include a contact hole through which the first connection electrode CNE1 passes. The contact hole of the first interlayer dielectric layer 133 may be connected to the contact hole of the gate insulator 131 and a contact hole of the second interlayer dielectric layer 135.

The capacitor electrode CPE may be disposed on the first interlayer dielectric layer 133. The capacitor electrode CPE may overlap with the gate electrode GE in the thickness direction. The capacitor electrode CPE and the gate electrode GE may form a capacitance.

The second interlayer dielectric layer 135 may cover the capacitor electrode CPE and the first interlayer dielectric layer 133. The second interlayer dielectric layer 135 may include a contact hole through which the first connection electrode CNE1 passes. The contact hole of the second interlayer dielectric layer 135 may be connected to the contact hole of the first interlayer dielectric layer 133 and the contact hole of the gate insulator 131.

The first connection electrode CNE1 may be disposed on the second interlayer dielectric layer 135. The first connection electrode CNE1 may electrically connect the drain electrode DE of the thin-film transistor TFT with the second connection electrode CNE2. The first connection electrode CNE1 may be inserted into a contact hole formed in the second interlayer dielectric layer 135, the first interlayer dielectric layer 133 and the gate insulator 131 to be in contact with the drain electrode DE of the thin-film transistor TFT.

The first passivation layer 137 may cover the first connection electrode CNE1 and the second interlayer dielectric layer 135. The first passivation layer 137 can protect the thin-film transistor TFT. The first passivation layer 137 may include a contact hole through which the second connection electrode CNE2 passes.

The second connection electrode CNE2 may be disposed on the first passivation layer 137. The second connection electrode CNE2 may electrically connect the first connection electrode CNE1 with the pixel electrodes AE1 and AE2 of the light-emitting elements ED1 and ED2. The second connection electrode CNE2 may be inserted into a contact hole formed in the first passivation layer 137 to be in contact with the first connection electrode CNE1.

The second passivation layer 139 may cover the second connection electrode CNE2 and the first passivation layer 137. The second passivation layer 139 may include contact holes through which the pixel electrodes AE1 and AE2 of the light-emitting elements ED1 and ED2 pass.

A light-emitting element layer 150 may be disposed on the first thin-film transistor layer TFTL1. The light-emitting element layer 150 includes a pixel-defining layer 151 that defines the emission areas of the first blue pixel SP(B1) and the red pixel SP(R) (e.g., first pixel area SPN1 and second pixel area SPN2), and a plurality of light-emitting elements ED1 and ED2 respectively disposed in the emission areas of the first blue pixel SP(B1) and the red pixel SP(R). The light-emitting elements ED1 and ED2 may include the pixel electrodes AE1 and AE2, light-emitting structures EL1 and EL2, and a common electrode, respectively.

The plurality of light-emitting elements ED1 and ED2 may include a first light-emitting element ED1 disposed in the emission area of the first blue pixel SP(B1) (i.e., the first pixel area SPN1), and a second light-emitting element ED2 disposed in the emission area of the red pixel SP(R) (e.g., the second pixel area SPN2). The light-emitting elements ED1 and ED2 may emit lights of different colors, such as blue and white, depending on the materials of the light-emitting structures EL1 and EL2. For example, the first light-emitting element ED1 disposed in the emission area of the first blue pixel SP(B1) may emit blue light, and the second light-emitting element ED2 disposed in the emission area of the red pixel SP(R) may emit red light. Two emission areas (e.g., the first pixel area SPN1 and the second pixel area SPN2) forming a single unit pixel may include the respective light-emitting elements ED1 and ED2 that may emit light of different colors, and which may represent black-and-white images or grayscale images.

The pixel electrodes AE1 and AE2 may be formed on the second passivation layer 139. The pixel electrodes AE1 and AE2 may be disposed in line with the emission areas (e.g., the first pixel area SPN1 and the second pixel area SPn2), respectively. The pixel electrodes AE1 and AE2 may be electrically connected to the drain electrode DE of the thin-film transistor TFT through the first and second connection electrodes CNE1 and CNE2. The pixel electrodes AE1 and AE2 may include a first pixel electrode AE1 disposed in the first pixel area SPN1 and a second pixel electrode AE2 disposed in the second pixel area SPN2. The first pixel electrode AE2 and the second pixel electrode AE2 may be spaced apart from each other on the second passivation layer 139.

The first and second pixel electrodes AE1 and AE2 may include indium-tin-oxide (ITO), indium-zinc-oxide (IZO), zinc oxide (ZnO) and indium oxide (In₂O₃) and may include a material that is transparent and has a high work function. If the pixel electrodes AE1, AE2 and AE3 are reflective electrodes, they may have a stack structure in which the material layer having a high work function, and a reflective material such as silver (Ag), magnesium (Mg), aluminum (Al), platinum (Pt), lead (Pb), gold (Au), nickel (Ni), neodymium (Nd), iridium (Ir), chrome (Cr), lithium (Li), or calcium (Ca) or a mixture thereof, and stacked. For example, the pixel electrodes AE1 and AE2 may have, but is not limited to, a multilayer structure of ITO/Mg, ITO/MgF, ITO/Ag, or ITO/Ag/ITO.

The second display panel 100 may include a pixel-defining layer 151 disposed over the second passivation layer 139 and the pixel electrodes AE1 and AE2. The pixel-defining layer 151 defines the first pixel area SPN1, the second pixel area SPN2, and the light-transmitting area ON. The pixel-defining layer 151 may be formed on the front surface of the second passivation layer 139, and the front surfaces of the pixel electrodes AE1 and AE2 may be exposed by the respective openings.

The pixel-defining layer 151 may be formed as a double layer including an inorganic or organic insulating material layer BS1, and an inorganic insulating material layer BS2 containing a fluorine-based material. For example, the pixel-defining layer 151 may be formed as a double layer including an inorganic insulating material layer BS1 containing silicon and an inorganic insulating material layer BS2 containing a fluorine-based material. For example, the inorganic insulating material layer BS1 may include an inorganic insulating material such as silicon oxide (SiO₂), silicon nitride (Si₃N₄), or silicon oxynitride (Si₂N₂O). The inorganic insulating material layer BS2 containing a fluorine-based material may include inorganic insulating materials such as fluorine-based silicon oxide (F—SiO₂), fluorine-based silicon nitride (F—Si₃N₄) or fluorine-based silicon oxynitride (F—Si₂N₂O) containing fluorine-based elements.

The light-emitting structures EL1 and EL2 may be disposed on the pixel electrodes AE1 and AE2, respectively. The light-emitting structures EL1 and EL2 of the light-emitting elements ED1 and ED2 may emit lights as the thin-film transistor TFT applies predetermined voltages to the pixel electrodes AE1 and AE2 of the light-emitting elements ED1 and ED2, and the common electrode CE of the light-emitting elements ED1 and ED2 receives a common voltage or cathode voltage.

The light-emitting structures EL1 and EL2 may include a first light-emitting structure EL1 and a second light-emitting structure EL2 disposed in different first and second pixel areas SPN1 and SPN2, respectively. The first light-emitting structure EL1 may be disposed on the first pixel electrode AE1 in the emission area of the first pixel area SPN1, and the second light-emitting structure EL2 may be disposed on the second pixel electrode AE2 in the emission area of the second pixel area SPN2.

The common electrode CE may be disposed on the light-emitting structures EL1 and EL2. The common electrode CE may cover the light-emitting structures EL1 and EL2 located in the first pixel area SPN1 and the second pixel area SPN2, and the pixel-defining layer 151. The common electrode CE may include a transparent conductive material so that light generated in the light-emitting structures EL1 and EL2 can exit. The common electrode CE may receive a common voltage or a low-level voltage. When the pixel electrodes AE1 and AE2 receive the voltage equal to the data voltage and the common electrode CE receives the low-level voltage, a potential difference is created between the pixel electrodes AE1 and AE2 and the common electrode CE, so that the light-emitting structures EL1 and EL2 can emit light. The common electrode CE may include a material layer having a small work function such as Li, Ca, LiF/Ca, LiF/Al, Al, Mg, Ag, Pt, Pd, Ni, Au, Nd, Ir, Cr, BaF, or Ba, or a compound or mixture thereof (e.g., a mixture of Ag and Mg). The common electrode CE may further include a transparent metal oxide layer disposed on the material layer having a small work function.

The common electrode CE may include a capping layer on a transparent conductive metal layer. The capping layer may protect the transparent conductive metal. Specifically, the common electrode CE may be a single layer containing a conductive metal or a multilayer layer containing a conductive metal and a capping layer. A space SA may be defined by a gap over the common electrode CE in line with the emission area of each of the first pixel area SPN1 and the second pixel area SPN2. The space SA may be capped by the first protective layer TIN1.

An organic or inorganic layer made of a transparent material may be formed in the light-transmitting area ON. An opening may be further formed in the light-transmitting area ON. The opening in the light-transmitting area ON may increase transmittance of the second display panel 100. For example, the opening in the light-transmitting area ON may extend in a direction opposite to the Z direction to the substrate SUB. The opening in the light-transmitting area ON may be capped by the first protective layer TIN1.

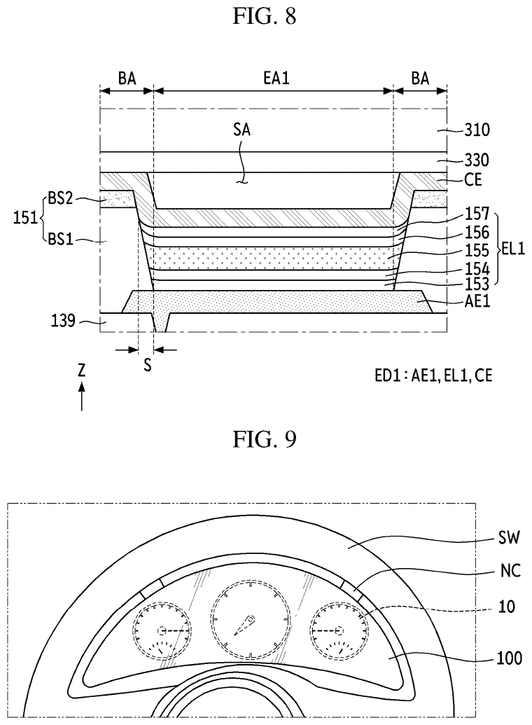

FIG. 8 is an enlarged cross-sectional view of a light-emitting unit of the first blue pixel shown in FIG. 7.

Referring to FIG. 8, a first light-emitting structure EL1 may include a hole injection layer 153, a hole transport layer 154, an organic light-emitting layer 155, an electron transport layer 156 and an electron injection layer 157.

The hole injection layer 153 may be disposed on the pixel electrodes AE1 and AE2. The hole injection layer 153 may facilitate injection of holes from the pixel electrodes AE1 and AE2 into the organic light-emitting layer 155.

For example, the hole injection layer 153 may include a phthalocyanine compound such as copper phthalocyanine, or a polyether ketone (TPAPEK) containing triphenylamine.

The hole transport layer 154 may be disposed on the hole injection layer 153. The hole transport layer 154 may facilitate transport of holes from the pixel electrodes AE1 and AE2 into the organic light-emitting layer 155. The hole transport layer 154 may include, for example, carbazole-based derivatives such as N-phenylcarbazole and polyvinylcarbazole, fluorene-based derivatives, triphenylamine-based derivatives, etc.

The organic light-emitting layer 155 may be disposed on the hole transport layer 154. The organic light-emitting layer 155 may include a plurality of quantum dots.

The organic light-emitting layer 155 may emit light as electron-hole pairs are combined therein in response to an electrical signal applied through the pixel electrode AE1 and AE2. To this end, the organic light-emitting layer 155 may include a material having a single or multiple quantum well structure. When the organic light-emitting layer 155 includes a material having the multiple quantum well structure, well layers and barrier layers may be alternately stacked on one another in the structure. The well layers may be made of InGaN, and the barrier layers may be made of GaN or AlGaN, but the present disclosure is not limited thereto. The thickness of the well layers may be approximately 1 nm to 4 nm, and the thickness of the barrier layers may be 3 nm to 10 nm.

Alternatively, the organic light-emitting layer 155 may have a structure in which a semiconductor material having a large band gap energy and a semiconductor material having a small band gap energy may be alternately stacked on one another, and may include other Group III to Group V semiconductor materials depending on the wavelength range of the emitted light. The light emitted from the organic light-emitting layer 155 is not limited to red light or white light. The organic light-emitting layer 155 may emit one of blue, green, or red lights. However, embodiments are not limited thereto, and the organic light-emitting layer 155 may emit light of a different color.

Specifically, the color of the light emitted from the organic light-emitting layer 155 may vary depending on the content of indium (In). For example, as the content of indium (In) is larger or higher, the wavelength range of light emitted from the organic light-emitting layer 155 may move to the red wavelength range, and as the content of indium (In) is less or lower, the wavelength range of the emitted light may move to the blue wavelength range.

If the content of indium (In) is equal to or greater than about 35%, the organic light-emitting layer 155 may emit the light in the red wavelength range having a main peak wavelength from about 600 nm to about 750 nm. Alternatively, if the content of indium (In) is equal to about 25%, the organic light-emitting layer 155 may emit the light in the green wavelength range having a main peak wavelength from about 480 nm to about 560 nm. Alternatively, if the content of indium (In) is equal to or less than about 15%, the organic light-emitting layer 155 may emit the light in the blue wavelength range having a main peak wavelength from about 370 nm to about 460 nm.

The electron transport layer 156 may be disposed on the organic light-emitting layer 155. The electron transport layer 156 may facilitate injection and transport of electrons from the common electrode CE to the organic light-emitting layer 155. The electron transport layer 156 may be formed of a composition for the electron transport layer, and the composition for the electron transport layer may contain inorganic particles. The inorganic particles may include metal oxides. For example, the electron transport layer 156 of the second display panel 100 may include, but is not limited to, ZnMgO or ZnO.

FIG. 9 is a view showing a displayed image indicating information about the status of a vehicle as the first and second display panels are superimposed during driving.

Referring to FIG. 1 and FIG. 9, the first display panel 10 may be fixedly disposed at the location GB of the vehicle where information about the status of the vehicle is displayed (e.g., the location of the instrument cluster). The second display panel 100 may be fastened to a steering wheel SW by a separate fastening member NC, and may be located in the front of the first display panel 10 depending on the rotational position of the steering wheel SW.

The separate fastening member NC may be an adhesive, for example. The separate fastening member NC may be a device for securing the second display panel 100. For example, the separate fastening member NC may be a channel into which an edge of the second display panel 100 may be mounted. Further, the separate fastening member NC may be a clip extending to the second display panel 100 for fixing a location thereof.

The first display panel 10 applied to the dashboard of a vehicle may display in predetermined divided areas the information about the status of the vehicle, navigation information, audio and video content information, air conditioning device control information, or electronic device control information for controlling options and functions.

During driving the vehicle, the first display panel 10 may display the information about the status of the vehicle on predetermined divided areas under the control of the plurality of first data driver circuits 20 and the first display driver circuit 40. On the other hand, the second display panel 100 may remain turned off or may be maintained having a translucent state, for example, allowing greater than about 90% of light to pass.

At this time, even when the second display panel 100, which may be translucent, is moved and located to be superimposed in the front of the first display panel 10, the driver can see the information about the status of the vehicle displayed on the first display panel 10.

The second display panel 100 may display an image based on a rotation of a steering wheel. For example, the image displayed by the second display panel 100 may be aligned to an image displayed by the first display panel 10. For example, a vehicle control system, described herein, may detect a position of the steering wheel and may display an image aligned to the image displayed by the first display panel 10 based on the detected position of the steering wheel.

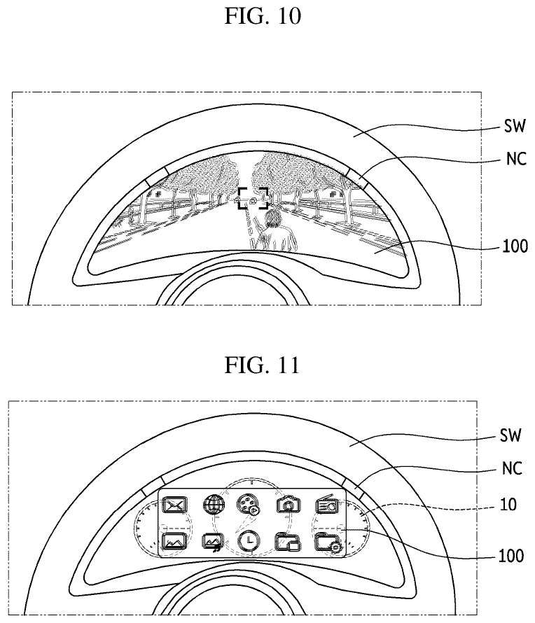

FIG. 10 is a view showing a content image when the first and second display panels are superimposed while the vehicle is stationary. FIG. 11 is another view showing a content image when the first and second display panels are superimposed while the vehicle is stationary.

Referring to FIG. 10 and FIG. 11, the first display panel 10 and the second display panel 100 may display either the same image or different images. According to an embodiment, the same image displayed by the first display panel 10 and the second display panel 100 may include slightly different versions of the same image generated to create an impression of depth of field.

As an example, the first display panel 10 and the second display panel 100 may display the same image while the vehicle is stationary. At this time, a user at the driver's seat can perceive a three-dimensional image effect due to the distance difference between the first display panel 10 and the second display panel 100. For example, an apparent three-dimensional image effect with continuous depth between the two image planes displayed by the first display panel 10 and the second display panel 100, respectively, when two versions of the same image are overlapped from a point-of-view of the user's eyes. The versions of the image may be, for example, stereoscopic images or anaglyph images. For example, in a case that the first display panel 10 and the second display panel 100 are overlapping from the point-of-view of the user's eyes, a volumetric image may be perceived.

On the other hand, the first display panel 10 and the second display panel 100 may display different images. For example, the first display panel 10 may display the information about the status of the vehicle on predetermined divided areas under the control of the plurality of first data driver circuits 20 and the first display driver circuit 40. In addition, the second display panel 100 may display content images pursuant to a user's touch under the control of the plurality of second data driver circuits 200 and the second display driver circuit 400.

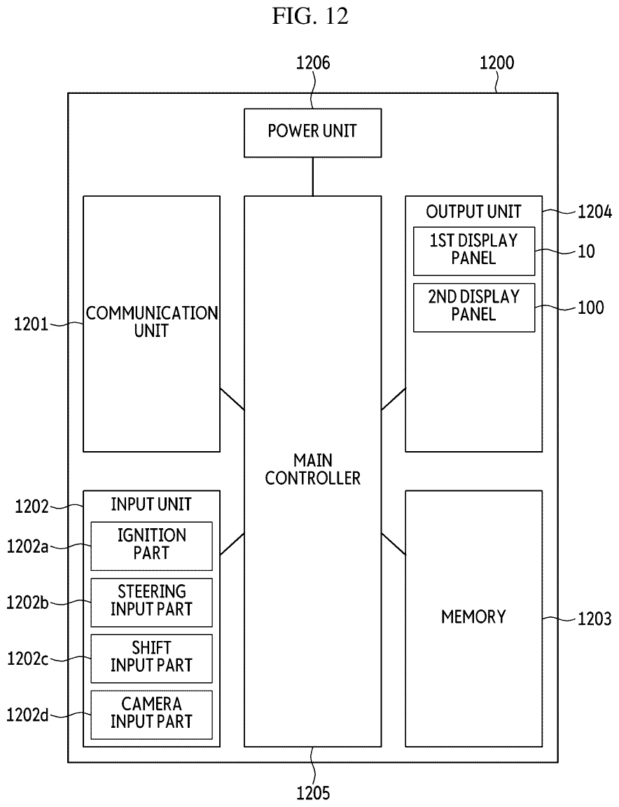

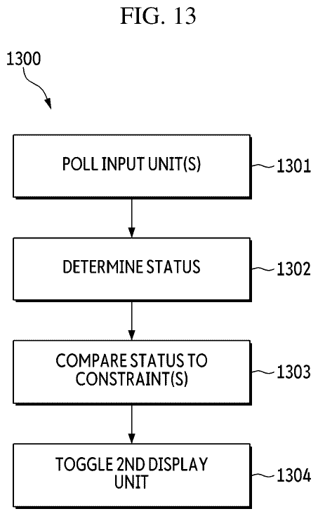

FIG. 12 is a schematic block diagram illustrating a vehicle control system according to an embodiment of the present disclosure.

Referring to FIG. 12, the vehicle control system 1200 may include a communication unit 1201, an input unit 1202, a memory 1203, an output unit 1204, a main controller 1205, and a power unit 1206. The vehicle control system 1200 may be electrically connected to the first and second display panels 10 and 100.

The communication unit 1201 may be used for communication with vehicle control system 1200. For example, the communication unit 1201 may support a vehicle-to-vehicle communication (V2V) protocol or a vehicle-to-infrastructure communication (V2I) protocol, which may be implemented for communication with vehicle control system 1200. The communication unit 1201 may support technologies including, for example, BLUETOOTH™, Radio Frequency Identification (RFID), Infrared Data Association (IrDA), Ultra-WideBand (UWB), ZigBee, Near Field Communication (NFC), Wireless-Fidelity (Wi-Fi), Wi-Fi Direct, or Wireless Universal Serial Bus (USB).

The input unit 1202 may receive inputs from systems of the vehicle. For example, the input unit 1202 may receive an input from an ignition part 1202a, a steering input part 1202b, a shift input part 1202c, or a camera input part 1202d. The vehicle control system 1200 may determine a status of the vehicle based on a signal from the input unit 1202. For example, the vehicle control system 1200 may determine that the vehicle is stationary based on an output of the ignition part 1202a and/or the shift input part 1202c, or that the first and second display panels 10 and 100 are superimposed based on a signal of the steering input part 1202b.

The memory 1203 may be electrically connected to the main controller 1205. The memory 1203 may store data for each unit, may control data for operation control of the unit, and may input/output data. The memory 1203 may be various hardware storage devices such as a ROM, a RAM, an EPROM, a flash drive, or a hard drive. The memory 1203 may store various data for overall operations of the vehicle control system 1200, such as programs for processing or control of the main controller 1205.

The output unit 1204 may be used to output information processed by the main controller 1205, and may include the first and second display panels 10 and 100. The output unit 1204 may include other units. For example, the output unit 1204 may include a sound output unit or a haptic output unit.

The main controller 1205 may control an operation of the vehicle control system 1200 to correspond to input information from the input unit 1202, for example, signals received from the steering input part 1202b. The main controller 1205 may control the first display driver circuit 40 and the second display driver circuit 400. For example, the main controller 1205 may adjust an image displayed by at least one of the first and second display panels 10 and 100 according to an alignment determined using an output of the steering input part 1202b and a current gaze of the user determined using a camera input part 1202d, which may be used to track the gaze of the user. For example, an alignment of images display by the first and second display panels 10 and 100 may be ensured for the point of view of the user.

FIG. 13 is a flow diagram illustrating a method according to an embodiment of the present disclosure.

Referring to FIG. 13, a method 1300 for controlling the second display device may include polling an input unit at step 1301, determining a status at step 1302, comparing the status to a constraint at step 1303, and toggling the second display device at step 1304. Polling the input unit at step 1301 may include, for example, the main controller 1205 polling the shift input part 1202c for a status of a transmission or a drive mode. In another example, the main controller 1205 may poll the steering input part 1202b for a rotational angle of the steering wheel or to determining whether the user's hands are on the steering wheel. A status of the vehicle may be determined at step 1302 based on the polling. For example, the main controller 1205 may determine that the vehicle is parked. The status may be compared to one or more constraints at step 1303. For example, one or more constraints may be enforced, which may control whether the second display device may be toggled on or off. For example, the second display panel 100 may be turned on at step 1304 when the vehicle is parked. In another example, the second display panel 100 may be turned off at step 1304 when the steering wheel is turning so that the second display panel 100 is no longer aligned with the first display device 10. In still another example, the brightness of the second display panel 100 may be adjusted based on the inputs, status, and constraints. It should be understood that embodiments are not limited thereto, and other inputs, status, constraints, and toggling are possible.

As described herein, the display device according to an embodiment of the present disclosure allows images of information about the status of the vehicle or three-dimensional content images to be displayed on the first and second display panels 10 and 100 selectively depending on whether the driver is driving or the vehicle is stationary, thereby helping the driver use the image display devices more safely in the vehicle.

In concluding the detailed description, those skilled in the art will appreciate that many variations and modifications can be made to preferred embodiments without substantially departing from the principles of the present disclosure. Therefore, embodiments of the disclosure may be used in a generic and descriptive sense only and not for purposes of limitation.

What is claimed is:

1. A display device comprising:
a first display panel comprising a plurality of first sub-pixels;
a first display driver circuit configured to control an image display operation of the first display panel;
a second display panel disposed in front of the first display panel and comprising a plurality of second sub-pixels and a plurality of light-transmitting areas disposed adjacent to the plurality of second sub-pixels; and
a second display driver circuit configured to control an image display operation of the second display panel,
wherein the second display panel is superimposed with the first display panel at a predetermined distance.

2. The display device of claim 1, wherein the first display panel is fixedly disposed at a location in a vehicle, and
wherein the second display panel is disposed on a dashboard in front of the first display panel to be superimposed with the first display panel at the predetermined distance.

3. The display device of claim 1, wherein the first display panel is fixedly disposed at a location in a vehicle, and
wherein the second display panel is disposed on a steering wheel disposed in front of the first display panel with a rotational position of the steering wheel.

4. The display device of claim 3,
wherein the plurality of light-transmitting areas are transparent and transmit light therethrough.

5. The display device of claim 3, wherein an image display unit of the second display panel comprises:
a first pixel area comprising at least one sub-pixel of the plurality of second sub-pixels;
a second pixel area comprising at least one sub-pixel of the plurality of second sub-pixels different from the first pixel area; and
a light-transmitting area of the plurality of light-transmitting areas that is transparent and transmits light therethrough.

6. The display device of claim 5, wherein the first pixel area, the second pixel area, and the light-transmitting area are sequentially and repeatedly arranged in parallel in parallel stripes in the image display unit of the second display panel.

7. The display device of claim 5, wherein the first pixel area comprises first and second sub-pixels of the plurality of second sub-pixels overlapping each other and formed as a double layer,
wherein the second pixel area comprises third and fourth sub-pixels of the plurality of second sub-pixels overlapping each other and formed as a double layer, and
wherein the light-transmitting area comprises a substrate and at least one of a transparent inorganic layer or a transparent organic layer.

8. The display device of claim 5, wherein the first pixel area comprises first and second blue sub-pixels of the plurality of second sub-pixels overlapping each other and formed as a double layer,
wherein the second pixel area comprises red and green sub-pixels of the plurality of second sub-pixels overlapping each other and formed as a double layer, and
wherein the light-transmitting area comprises a substrate, at least one of a transparent inorganic layer or a transparent organic layer, and at least one opening.

9. A display device comprising:
a first display panel configured to display a first image or a second image through a plurality of first sub-pixels;
a first display driver circuit configured to control an image display operation of the first display panel;
a second display panel in which a plurality of second sub-pixels and a plurality of light-transmitting areas are alternately arranged to display the second image through the plurality of second sub-pixels;
a second display driver circuit configured to control an image display operation of the second display panel; and
a touch sensing unit formed on a front surface of the second display panel,
wherein the plurality of light-transmitting areas of the second display panel is configured to transmit light emitted by the first display panel, and the second display panel is superimposed with the first display panel at a predetermined distance in front of the first display panel.

10. The display device of claim 9, wherein the first display panel is fixedly disposed at a location in a vehicle, and
wherein the second display panel is fastened to a steering wheel by at least one fastening member and disposed in front of the first display panel with a rotational position of the steering wheel.

11. The display device of claim 10, wherein at least two sub-pixels of the plurality of second sub-pixels and a light-transmitting area of the plurality of light-transmitting areas are sequentially arranged in parallel stripes to one another in an image display unit of the second display panel, and
wherein the light-transmitting area is transparent and transmits light therethrough.

12. The display device of claim 10, wherein an image display unit of the second display panel comprises:
a first pixel area comprising at least one sub-pixel of the plurality of second sub-pixels;
a second pixel area comprising at least one sub-pixel the plurality of second sub-pixels different from the first pixel area; and
a light-transmitting area of the plurality of light-transmitting areas that is transparent and transmits light therethrough.

13. The display device of claim 12, wherein the first pixel area, the second pixel area and the light-transmitting area are sequentially and repeatedly arranged in parallel stripes in the image display unit of the second display panel.

14. The display device of claim 12, wherein the first pixel area comprises first sub-pixels and second sub-pixels of the plurality of second sub-pixels overlapping each other and formed as a double layer,
wherein the second pixel area comprises third and fourth sub-pixels of the plurality of second sub-pixels overlapping each other and formed as a double layer, and
wherein the light-transmitting area comprises a substrate and at least one of a transparent inorganic layer or a transparent organic layer.

15. The display device of claim 12, wherein the first pixel area comprises first and second blue sub-pixels of the plurality of second sub-pixels overlapping each other and formed as a double layer,
wherein the second pixel area comprises red and green sub-pixels of the plurality of second sub-pixels overlapping each other and formed as a double layer, and
wherein the light-transmitting area comprises a substrate, at least one of a transparent inorganic layer or a transparent organic layer, and at least one opening.

16. A vehicle control system comprising:
a first display panel including a first plurality of sub-pixels;
a first display driver circuit configured to control an operation of the first display panel;
a second display panel rotatably disposed in front of the first display panel and including a second plurality of sub-pixels and light-transmitting areas; and
a second display driver circuit configured to control an operation of the second display panel.

17. The vehicle control system of claim 16, wherein the first display panel is fixedly disposed in a vehicle, and
wherein the second display panel is disposed on a steering wheel disposed in front of the first display panel with a rotational position of the steering wheel.

18. The vehicle control system of claim 17, further comprising:
an input unit configured to sense a status of the vehicle; and
a main controller electrically connected to the second display driver circuit and configured to control the second display driver circuit based on the status of the vehicle.

19. The vehicle control system of claim 18, wherein the input unit further comprises a steering input part configured to output a rotational position of the steering wheel to the main controller.

20. The vehicle control system of claim 18, wherein the input unit further comprises a camera input part configured to output a gaze of a user to the main controller.
